(19) United States
(12) Patent Application Publication
(10) Pub. No.: US 2004/0130517 A1
(43) Pub. Date: Jul. 8, 2004

(54) PIXEL STRUCTURE OF ACTIVE MATRIX DISPLAY DEVICE

(76) Inventor: Chun-Huai Li, Ping-Tung Hsien (TW)

Correspondence Address: NAIPO (NORTH AMERICA INTERNATIONAL PATENT OFFICE), P.O. BOX 506, MERRIFIELD, VA, 22116, US

(21) Appl. No.: 10/707,646

(22) Filed: Dec. 30, 2003

(30) Foreign Application Priority Data
Jan. 3, 2003 (TW) 092100148

(51) Int. Cl. G09G 3/32

(52) U.S. Cl. 345/82

(57) ABSTRACT

A pixel structure of an active matrix display device includes a storage capacitor, a first active device having a first end electrically connected to a scanning line, a second end electrically connected to a data line, a third end electrically connected to the storage capacitor, and a plurality of active-type light emitting devices electrically connected in parallel with each other between a source of first potential, a source of second potential, and the third end.

### BACKGROUND OF INVENTION

1. Field of the Invention

The present invention relates to a pixel structure of an active matrix display device, and more specifically, to a pixel structure of an organic light emitting display device.

2. Description of the Prior Art

In various types of flat panel displays, since an organic light emitting diode (OLED) has many beneficial characteristics, such as having a spontaneous light source, a wide viewing angle, a high response velocity, full-color, a simpler structure, a wide operating temperature, and power saving properties, the OLED has been used extensively in small and medium scale portable display fields.

Please refer to FIG. 1. FIG. 1 is a schematic diagram of a prior art organic light emitting display device 10. The organic light emitting display device 10 comprises a display panel 12, a scanning line driving circuit 14, and a data line driving circuit 16. The display panel 12 includes a plurality of scanning lines 18 (i.e. SL₁-SLₘ), a plurality of data lines 20 (i.e. DL₁-DLₙ) that are perpendicular to the scanning lines 18, and a plurality of pixels 22 connected to the scanning lines 18 and the data lines 20. Furthermore, the scanning line driving circuit 14 and the data line driving circuit 16 input respective signals to the scanning lines 18 and the data lines 20. Accordingly, each of the pixels 22 can receive corresponding signals via the scanning lines 18 and the data lines 20, and can display a gray level according to the corresponding signals. The organic light emitting display device 10 can therefore display an image that is composed of the gray levels displayed by the pixels 22.

Please refer to FIG. 2. FIG. 2 is a circuit diagram of one of the pixels22 shown in FIG. 1. As shown in FIG. 2, the pixel 22 comprises two thin film transistors 24 and 26, a storage capacitor 28, and an organic light emitting diode 30. The thin film transistor 24 includes a gate electrode 24a electrically connected to the scanning line 18, a drain electrode 24b electrically connected to the data line 20, and a source electrode 24c. Additionally, the thin film transistor 26 comprises a gate electrode 26a electrically connected to the source electrode 24c and one end of the storage capacitor 28, a source electrode 26c electrically connected to an external power supply V_{dd}, and a drain electrode 26b electrically connected to an anode 30a of the organic light emitting diode 30 whose cathode 30b is grounded.

As shown in FIG. 2, when the pixel 22 is on its operation mode, the scanning line driving circuit 14 inputs a scanning signal into the gate electrode 24a of the thin film transistor 24 via the scanning line 18 for turning on the thin film transistor 24. Thereafter, the data line driving circuit 16 inputs a corresponding data signal into the drain electrode 24b of the thin film transistor 24 through the data line 20 for turning on the thin film transistor 26. At the same time, the external power source V_{dd} provides a driving current to the organic light emitting diode 30 through the thin film transistor 26. Then, the driving current would make the organic light emitting diode 30 radiate light beams to display a corresponding gray level that is varied according to a quantity of the driving current.

Please refer to FIG. 3 and FIG. 4. FIG. 3 is a cross-sectional view of the organic light emitting diode 30 shown in FIG. 2. FIG. 4 is a top view of the organic light emitting diode shown in FIG. 3. As shown in FIG. 3, the organic light emitting diode 30 mainly comprises a glass substrate 32, a transparent conductive layer 34 located on the glass substrate 32 for being the anode 30a of the organic light emitting diode 30, a composite layer 36 located on the transparent conductive layer 34, and a metal layer 38 located on the composite layer 36 for being the cathode 30b of the organic light emitting diode 30. Additionally, the composite layer 36 is composed of a hole transporting layer 36a, a light emitting layer 36b, and an electron transporting layer 36c. The transparent conductive layer 34 is made from indium tin oxide (ITO) or indium zinc oxide (IZO), while the metal layer 38 is composed of magnesium (Mg), aluminum (Al), or an alloy of lithium (Li) and silver (Ag).

Unfortunately, an electrical shortage always occurs between the metal layer 38 and the transparent conductive layer 34 due to process errors or other factors. For example, a spike of the metal layer 38 is formed due to process errors and always perforates the composite layer 36 to contact with the transparent conductive layer 34, as is indicated by an array A in FIG. 3. Alternatively, an uneven surface of the transparent conductive layer 34 also causes the transparent conductive layer 34 to contact with the metal layer 38, as is indicated by an array B in FIG. 3. Because the resistances of the electrical shortages, indicated by the arrays A and B, are approximately equal to thousands of ohms (KΩ) and the resistance of the organic light emitting diode 30 is equal to millions of ohms (MΩ), most driving current will flow through not the organic light emitting diode 30 but the electrical shortages, indicated by the arrays A and B. Therefore, the organic light emitting diode 30 cannot radiate light beams, which leads to forming a defect on the organic light emitting display device 10.

As shown in FIG. 4, laser beams are always utilized in a prior art method to cut conjunction portions between the organic light emitting diode 30 and the electrical shortages, indicated by the arrays A and B. However, the laser beams usually cause the metal layer 38 surrounding the electrical shortages to contact with the transparent conductive layer 34, which leads to other electrical shortages. Therefore, the laser beams cannot effectively repair the defects on the organic light emitting display device 10.

Furthermore, the prior art method requires operators to find out the defects first, and then utilizes the laser beams to repair the defects, so that the prior art method requires a lot of time and manpower, and is quite uneconomical.

### SUMMARY OF INVENTION

It is therefore a primary objective of the claimed invention to provide a pixel structure of an organic light emitting display device to solve the above-mentioned problem.

According to the claimed invention, a pixel structure of an active matrix display device is provided. The pixel structure includes a storage capacitor, a first active device having a first end electrically connected to a scanning line, a second end electrically connected to a data line, a third end electrically connected to the storage capacitor, and a plurality of active-type light emitting devices electrically connected in parallel with each other between a source of first potential, a source of second potential, and the third end.

It is an advantage over the prior art that the claimed invention provides a pixel comprising a plurality of light emitting devices connected in parallel with each other. Each light emitting device is connected in series to an active device that is used to supply a driving current to the light emitting device. Therefore, when an electrical shortage occurs in one of the light emitting devices of a pixel, the pixel still can display an image via the other light emitting devices of the pixel. Therefore, it is unnecessary to utilize laser beams to repair defects, so that the production time can be saved and the yield can be effectively improved.

These and other objectives of the present invention will no doubt become obvious to those of ordinary skill in the art after reading the following detailed description of the preferred embodiment, which is illustrated in the multiple figures and drawings.

### BRIEF DESCRIPTION OF DRAWINGS

FIG. 1 is a schematic diagram of a prior art organic light emitting display device.

FIG. 2 is a circuit diagram of a pixel shown in FIG. 1.

FIG. 3 is a cross-sectional view of the organic light emitting diode shown in FIG. 2.

FIG. 4 is a top view of the organic light emitting diode shown in FIG. 3.

FIG. 5 is a schematic diagram of an active matrix display device according to the present invention.

FIG. 6 is a circuit diagram of a pixel shown in FIG. 5.

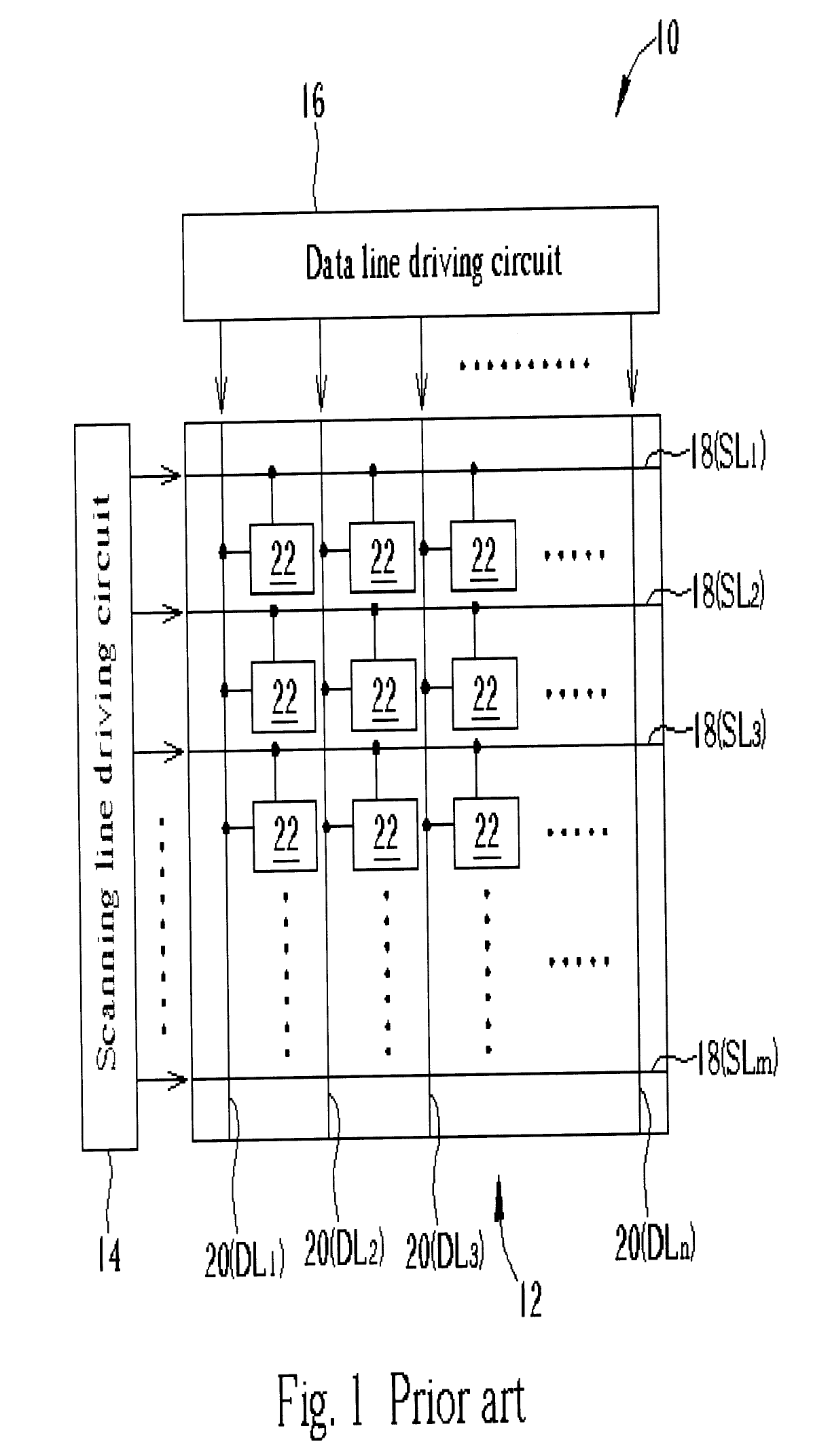

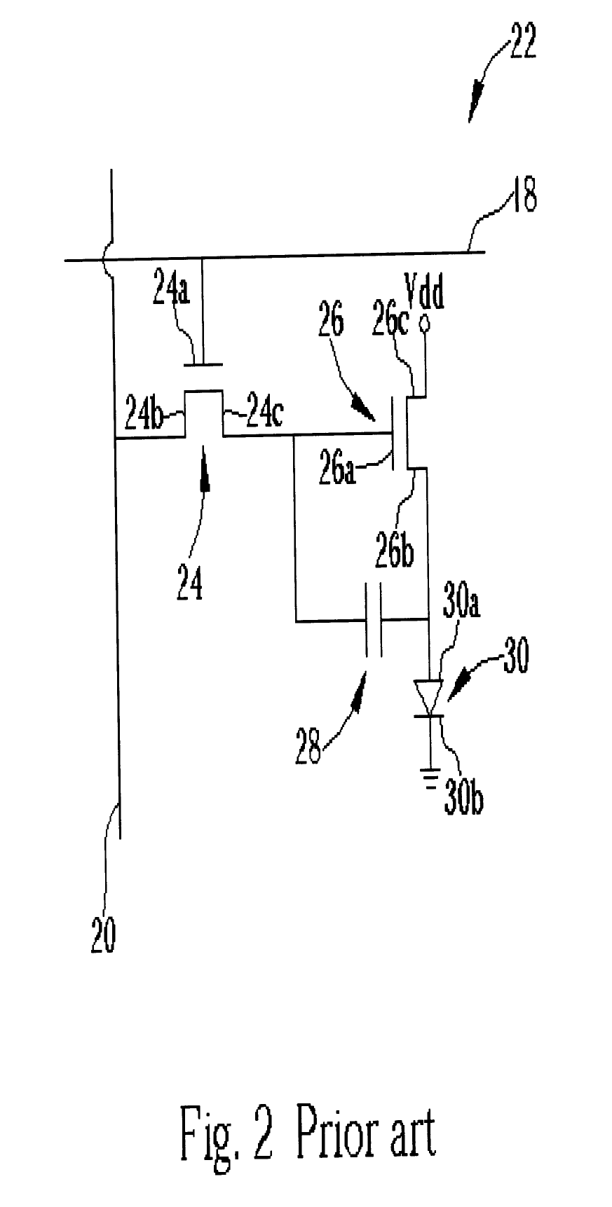

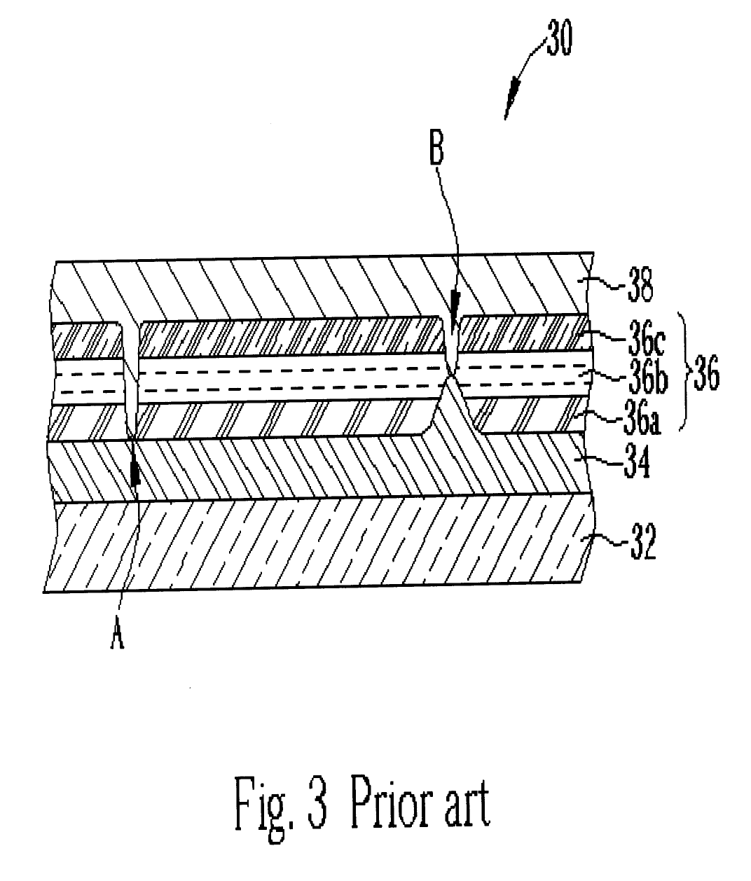

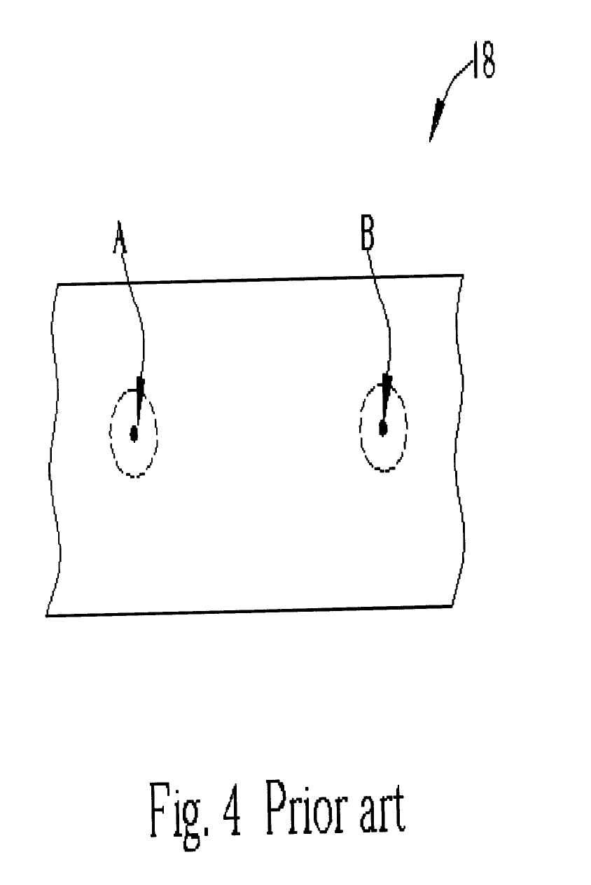

### DETAILED DESCRIPTION

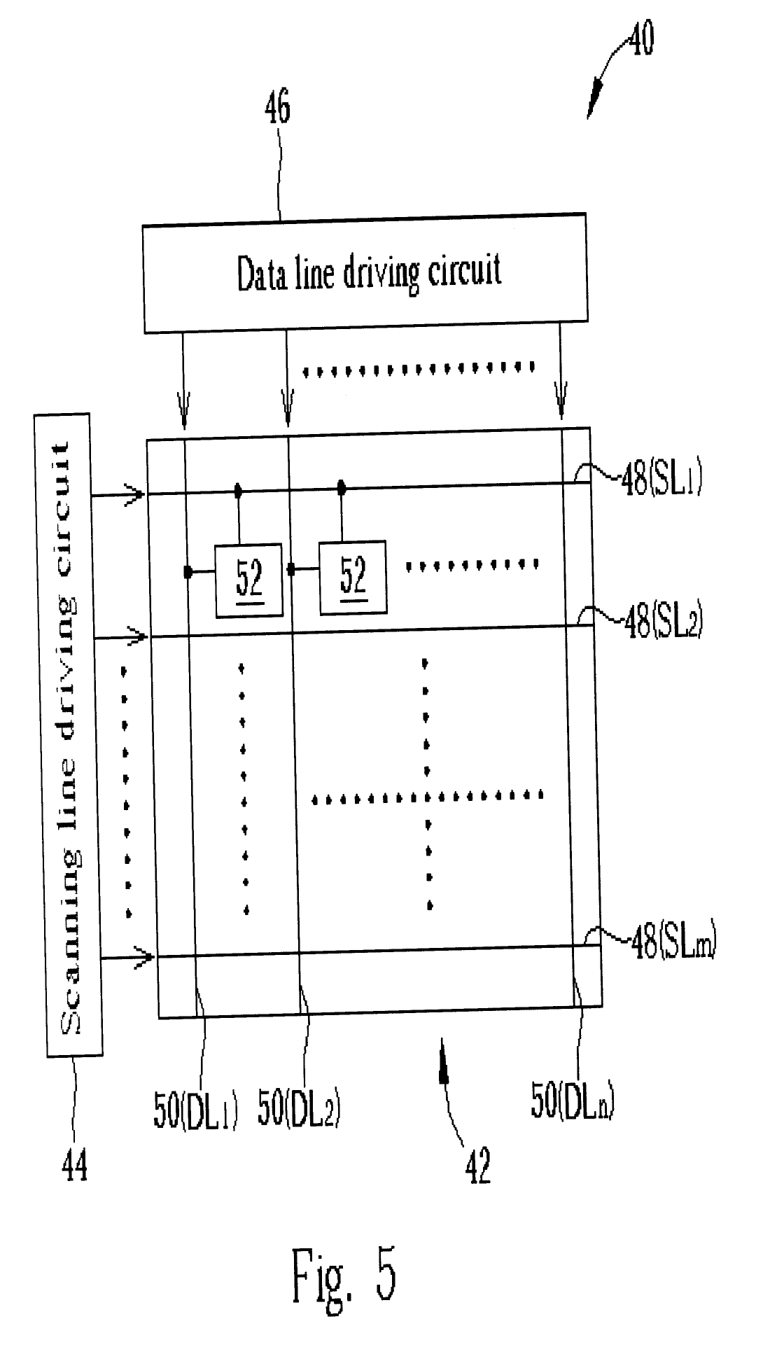

Please refer to FIG. 5. FIG. 5 is a schematic diagram of an active matrix display device according to the present invention. The active matrix display device 40 comprises a display panel 42, a scanning line driving circuit 44, and a data line driving circuit 46. The display panel 42 includes a plurality of scanning lines 48 (i.e. SL₁-SLₘ), a plurality of data lines 50 (i.e. DL₁-DLₙ) that are perpendicular to the scanning lines 48, and a plurality of pixels 52 that are electrically connected to the scanning lines 48 and the data lines 50. The scanning line driving circuit 44 and the data line driving circuit 46 respectively input signals to the scanning lines 48 and the data lines 50. Accordingly, each of the pixels 52 can receive corresponding signals via the scanning lines 48 and the data lines 50, and can display a gray level according to the corresponding signals. The organic light emitting display device 40 can therefore display an image that is composed of the gray levels displayed by the pixels 52.

Please refer to FIG. 6. FIG. 6 is a circuit diagram of one of the pixels 52 shown in FIG. 5. As shown in FIG. 6, the pixel 52 comprises a storage capacitor 54, an active device 56, and a plurality of active-type light emitting devices 58that are connected in parallel with each other.Each active-type light emitting device 58 comprises an active device 60 (T₁, T₂, T₃ or T₄) and a light emitting device 62 (D₁, D₂, D₃ or D₄). The active-type light emitting devices 58 are electrically connected between a potential source 64, a potential source 66, and an end 54a of the storage capacitor 54. Additionally, the potential source 64 is used to supply a potential V₁, while the potential source 66 is used to supply a potential V₂ that is a reference potential (ex. grounding potential) and is usually smaller than V₁. Furthermore, each of the active devices 56, 60 is a thin film transistor or a complementary metal-oxide semiconductor (CMOS), and each of the light emitting devices 62 is an organic light emitting diode or a light emitting diode (LED).

In the preferred embodiment of the present invention, the active matrix display device 40 is an organic light emitting display device. Accordingly, each of the light emitting devices 62 is an organic light emitting diode, while the active device 56 is a thin film transistor comprising a gate electrode 56a electrically connected to the scanning line 48, a drain electrode 56b electrically connected to the data line 50, and a source electrode 56c electrically connected to the end 54a of the storage capacitor 54. Furthermore, each of the active devices 60 is a thin film transistor comprising a gate electrode 60a electrically connected to the source electrode 56c of the thin film transistor 56, a source electrode 60c electrically connected to the potential source 64, and a drain electrode 60b electrically connected to an anode 62a of the organic light emitting diode 62 whose cathode 62b is electrically connected to the potential source 66. In addition, an end 54b of the storage capacitor 54 is electrically connected to the potential source 64, and moreover, the end 54b of the storage capacitor 54 also can be electrically connected to any other potential source capable of supplying a constant potential.

Additionally, the operating method of each pixel 52 is described as follows. Firstly, the scanning line driving circuit 44 inputs a scanning signal into the gate electrode 56a of the thin film transistor 56 through the scanning line 48. At the same time, the data line driving circuit 50 inputs a corresponding data signal into the drain electrode 56b of the thin film transistor 56 for turning on each of the thin film transistors 60 and charging the storage capacitor 54 to a first potential. Since each of the thin film transistors 60 is turned on, the potential source 64 supplies a driving current to each of the organic light emitting diodes 62 via the thin film transistors 60 to make the organic light emitting diodes 62 radiate light beams. When the thin film transistor 56 is turned off, the storage capacitor 54 still has the first potential for maintaining each thin film transistor 60 on a conductible state so that the thin film transistors 60 can supply driving currents to the organic light emitting diodes 62 for making the organic light emitting diodes 62 radiate light beams continuously.

Additionally, if the anode 62a and the cathode 62b of the organic light emitting diodes D₁ are contacted with each other due to process errors or other factors, an electrical storage occurs in the organic light emitting diodes 62 (ex. D₁). Accordingly, the driving current supplied by the thin film transistor T₁ cannot make the organic light emitting diodes D₁ radiate light beams. Noticeably, since the pixel 52 shown in FIG. 6 comprises four active light emitting devices 58 connected in parallel with each other, the thin film transistors T₂, T₃, and T₄ still can supply driving currents to the organic light emitting diodes D₂, D₃, and D₄. Therefore, the organic light emitting diodes D₂, D₃, and D₄ still can radiate light beams to maintain the pixel 52 on a luminous state. In other words, as long as at least one of the organic light emitting diodes 62 in a pixel 52 is good, the pixel 52 can radiate light beams normally. Therefore, it is unnecessary to utilize laser beams to repair defects in the present invention. As a result, the yield can be effectively improved.

In brief, the present invention provides a pixel comprising a plurality of active-type light emitting devices connected in parallel with each other. Each active-type light emitting device comprises an organic light emitting diode (or a light emitting diode), and a thin film transistor (or a CMOS) for supplying driving current to the organic light emitting diode. Additionally, a number of the active-type light emitting devices is decided according to a dimension of the pixel. Theoretically, when a number of the active-type light emitting devices gets higher and higher, the gray level of the pixel would not be influenced as an electrical shortage occurs in the organic light emitting diode of the pixel. Furthermore, the electrical circuit of a pixel is not limited to the pixel shown in FIG. 6.That is, amounts and positions of the thin film transistor 56 and the storage capacitor 54 can be modified according to actual requirements.

In contrast to the prior art, the present invention provides a pixel comprising a plurality of light emitting devices connected in parallel with each other. Each light emitting device is connected in series to an active device that is used to supply a driving current to the light emitting device. Therefore, when an electrical shortage occurs in one of the light emitting devices of a pixel, the pixel still can display an image via the other light emitting devices of the pixel. Therefore, it is unnecessary to utilize laser beams to repair defects, so that the production time can be saved and the yield can be effectively improved.

Those skilled in the art will readily observe that numerous modifications and alterations of the device may be made while retaining the teachings of the invention. Accordingly, the above disclosure should be construed as limited only by the metes and bound of the appended claims.

1. A pixel structure of an active matrix display device, the active matrix display device having a source of first potential and a source of second potential, the pixel structure comprising:
a storage capacitor;
a first active device having a first end electrically connected to a scanning line, a second end electrically connected to a data line, and a third end electrically connected to the storage capacitor; and
a plurality of active-type light emitting devices connected in parallel with each other, each of the active-type light emitting devices being electrically connected between the source of first potential, the source of second potential, and the third end.

2. The pixel structure of claim 1, wherein the first active device is a first thin film transistor, and the first end is a gate electrode of the first thin film transistor, the second end is a drain electrode of the first thin film transistor, and the third end is a source electrode of the first thin film transistor.

3. The pixel structure of claim 1, wherein the storage capacitor is electrically connected between the third end and a source of constant potential that is utilized for supplying a constant potential.

4. The pixel structure of claim 3, wherein the source of constant potential is the source of first potential.

5. The pixel structure of claim 1, wherein each of the active-type light emitting devices comprises:
a second active device having a fourth end connected to the third end, a fifth end connected to the source of first potential, and a sixth end; and
a light emitting device having a seventh end connected to the sixth end and an eighth end connected to the source of second potential.

6. The pixel structure of claim 5, wherein when an electrical shortage occurs in one of the light emitting devices, the pixel structure displays an image via the other light emitting devices.

7. The pixel structure of claim 5, wherein each of the second active devices comprises a second thin film transistor or a complementary metal-oxide semiconductor (CMOS).

8. The pixel structure of claim 7, wherein the fourth end is a gate electrode of the second thin film transistor, the fifth end is a source electrode of the second thin film transistor, and the sixth end is a drain electrode of the second thin film transistor.

9. The pixel structure of claim 5, wherein each of the light emitting devices comprises an organic light emitting diode (OLED) or a light emitting diode (LED).

10. The pixel structure of claim 9, wherein the seventh end is an anode of the light emitting device, and the eighth end serves as a cathode of the light emitting device.

11. Anactive matrix display device comprising:
a plurality of scanning lines;
a plurality of data lines;
a plurality of pixels, each of the pixels comprising:
a storage capacitor;
a first active device having a first end electrically connected to the corresponding scanning line, a second end electrically connected to the corresponding data line, and a third end electrically connected to the storage capacitor; and
a plurality of active-type light emitting devices electrically connected in parallel with each other, each of the active-type light emitting devices being connected between a source of first potential, a source of second potential, and the third end, each of the active-type light emitting devices comprising:
a light emitting device electrically connected to the source of second potential; and
a second active device having a fourth end electrically connected to the third end, a fifth end electrically connected to the source of first potential, and a sixth end electrically connected to the light emitting device.

12. The active matrix display device of claim 11, wherein the first active device is a first thin film transistor, and the first end is a gate electrode of the first thin film transistor, the second end is a drain electrode of the first thin film transistor, and the third end is a source electrode of the first thin film transistor.

13. The active matrix display device of claim 11, wherein the storage capacitor is electrically connected between the third end and a source of constant potential that is utilized for supplying a constant potential.

14. The active matrix display device of claim 13, wherein the source of constant potential is the source of first potential.

15. The active matrix display device of claim 11, wherein each of the second active devices comprises a second thin film transistor or a complementary metal-oxide semiconductor (CMOS).

16. The active matrix display device of claim 15, wherein the fourth end is a gate electrode of the second thin film transistor, the fifth end is a source electrode of the second thin film transistor, and the sixth end is a drain electrode of the second thin film transistor.

17. The active matrix display device of claim 11, wherein each of the light emitting devices comprises an organic light emitting diode (OLED) or a light emitting diode (LED).

18. The active matrix display device of claim 11, wherein when an electrical shortage occurs in one of the light emitting devices of a pixel, the pixel displays an image via the other light emitting devices of the pixel.
